(19) United States
(12) Patent Application Publication
(10) Pub. No.: US 2021/0398848 A1
(43) Pub. Date: Dec. 23, 2021

(54) METHOD FOR DEPOSITION OF HIGHLY SELECTIVE METAL FILMS

(71) Applicants: Merck Patent GmbH, Darmstadt (DE); THE REGENTS OF THE UNIVERSITY OF CALIFORNIA, Oakland, CA (US)

(72) Inventors: Ravindra KANJOLIA, North Andover, MA (US); Mansour MOINPOUR, SAN JOSE, CA (US); Jacob WOODRUFF, LEXINGTON, MA (US); Steven WOLF, San Diego, CA (US); Michael BREEDEN, San Diego, CA (US); Scott T. UEDA, Whittier, CA (US); Andrew KUMMEL, San Diego, CA (US); Ashay ANURAG, La Jolla, CA (US)

(73) Assignee: THE REGENTS OF THE UNIVERSITY OF CALIFORNIA, Oakland, CA (US)

(21) Appl. No.: 17/295,252

(22) PCT Filed: Dec. 3, 2019
(86) PCT No.: PCT/US2019/064113

§ 371 Date: May 19, 2021

Related U.S. Application Data
(60) Provisional application No. 62/774,695, filed on Dec. 3, 2018.

(51) Int. Cl. H01L 21/768; C23C 16/18; C23C 16/455

(52) U.S. Cl. CPC H01L 21/76879; C23C 16/18; H01L 23/53209; C23C 16/45553; C23C 16/45527

(57) ABSTRACT

The present inventive concept relates to selective metal layer deposition. Embodiments include a method for atomic layer deposition (ALD) of a metal, the method comprising at least one cycle of: a) exposing a substrate, the substrate comprising a surface comprising a metal portion and an insulator portion, to a metal-organic precursor; b) depositing a metal-organic precursor on an upper surface of the metal portion of the substrate to selectively provide a metal precursor layer on the upper surface of the metal portion of the substrate; c) exposing the metal precursor layer to a co-reactant; and d) depositing the co-reactant on the metal precursor layer, wherein the co-reactant takes part in a ligand exchange with the metal precursor layer.

### CROSS-REFERENCE TO RELATED APPLICATIONS

This application claims the benefit of U.S. Provisional Patent Application Ser. No. 62/774,695, filed Dec. 3, 2018, the entirety of which is incorporated herein by reference.

### STATEMENT REGARDING FEDERAL SUPPORT

This invention was made with government support under Grant No. HR0011-18-3-0004 awarded by the Department of Defense/Defense Advanced Research Projects Agency (DARPA). The government has certain rights in the invention.

### FIELD

The field of the invention is semiconductor device fabrication, in particular, highly selective deposition of metal films. Example applications of the invention include bottom-up fill of vias, patterning of integrated circuits, barrier layer applications, and formation of seed layers for copper deposition.

### BACKGROUND

Selective metal deposition is desirable for bottom-up fill for both middle-of-line (MOL or MEOL) and back end-of-line (BEOL) processing. Successful implementation would induce formation and growth of larger grains, which are expected to decrease via and interconnect resistance by reducing grain boundaries and decreasing surface roughness. In addition, bottom-up growth has the potential to eliminate the need for nucleation layers on low-k dielectrics (SiCOH) since the nucleation will occur only on the bottom surface. Key metals for bottom-up growth include cobalt and ruthenium; cobalt is particularly important since it used as both a capping layer on Cu to protect it from oxidation [Yang, C-C., et al. “Characterization of copper electromigration dependence on selective chemical vapor deposited cobalt capping layer thickness.” IEEE Electron Device Letters 32.4 (2011): 560-562], and in sub-10 nm vias, where Co is considered to be a better conductor than Cu due to Co having a smaller electron mean free path and problems with Cu electroplating in sub 10 nm vias [Gall, Daniel. “Electron mean free path in elemental metals.” Journal of Applied Physics 119.8 (2016): 085101].

Cobalt atomic layer deposition (ALD) has previously been reported by Charles Winter and colleagues. Klesko, Joseph P., Marissa M. Kerrigan, and Charles H. Winter. “Low Temperature Thermal Atomic Layer Deposition of Cobalt Metal Films.” Chemistry of Materials 28.3 (2016): 700-703; Kerrigan, Marissa M., et al. “Substrate selectivity in the low temperature atomic layer deposition of cobalt metal films from bis (1,4-di-tert-butyl-1,3-diazadienyl) cobalt and formic acid.” The Journal of Chemical Physics 146.5 (2017): 052813; Kerrigan, Marissa M., Joseph P. Klesko, and Charles H. Winter. “Low Temperature, Selective Atomic Layer Deposition of Cobalt Metal Films Using Bis (1,4-di-tert-butyl-1,3-diazadienyl) cobalt and Alkylamine Precursors.” Chemistry of Materials 29.17 (2017): 7458-7466; Winter et al., U.S. Pat. No. 9,255,327; Winter et al., US20180265975. Selectivity is not quantified in the work of Winter et al. In the cobalt layer ALD described by Winter et al., it was concluded that the HCOOH dissociatively chemisorbed to produce atomic H which removed the ligands from Co(DAD)₂. Other Co ALD techniques exist, but often require elevated temperatures and co-reactants such as O₂, which are incompatible with low k dielectrics such as SiCOH (methyl-terminated porous SiO₂) used in middle and back of line processing (MOL and BEOL). Furthermore, for MOL and BEOL, selectivity must be maintained on the nanoscale between the metal growth surface and the insulators. On patterned samples/substrates, selectivity under identical ALD conditions is often limited, due to the diffusion of molecularly-adsorbed metal precursor from reactive to non-reactive surfaces. As such, there is a need for improved methods of selective deposition of metal films, in particular, on the nanoscale on patterned samples.

### SUMMARY

Selective metal deposition is desirable for bottom-up fill for both middle-of-line (MOL or MEOL) and back end-of-line (BEOL) processing. Successful implementation would induce formation and growth of larger grains, which are expected to decrease via and interconnect resistance by reducing grain boundaries and decreasing surface roughness. In addition, bottom-up growth has the potential to eliminate the need for nucleation layers on low-k dielectrics (SiCOH) since the nucleation will occur only on the bottom surface. Key metals for bottom-up growth include cobalt and ruthenium; cobalt is particularly important since it used as both a capping layer on Cu to protect it from oxidation [Yang, C-C., et al. “Characterization of copper electromigration dependence on selective chemical vapor deposited cobalt capping layer thickness.” IEEE Electron Device Letters 32.4 (2011): 560-562], and in sub-10 nm vias, where Co is considered to be a better conductor than Cu due to Co having a smaller electron mean free path and problems with Cu electroplating in sub-10 nm vias [Gall, Daniel. “Electron mean free path in elemental metals.” Journal of Applied Physics 119.8 (2016): 085101].

According to an aspect of the invention, provided is a method for atomic layer deposition (ALD) of a metal, the method comprising at least one cycle of: a) exposing a substrate, the substrate comprising a surface comprising a metal portion and an insulator portion, to a metal-organic precursor; b) depositing a metal-organic precursor on a surface of the metal portion of the substrate to selectively provide a metal precursor layer on the surface of the metal portion of the substrate; c) exposing the metal precursor layer to a co-reactant; and d) depositing the co-reactant on the metal precursor layer, wherein the co-reactant takes part in a ligand exchange with the metal precursor layer.

According to another aspect of the invention, provided is a method for atomic layer deposition (ALD) of a metal, the method comprising at least one cycle of: a) exposing a substrate, the substrate comprising a surface comprising a metal portion and an insulator portion, to a zero-oxidation state liquid metal-organic precursor; b) depositing the zero-oxidation state liquid metal-organic precursor on an surface of the metal portion of the substrate to selectively provide a metal precursor layer on the surface of the metal portion of the substrate; c) exposing the metal precursor layer to a co-reactant; and d) depositing the co-reactant on the metal precursor layer, wherein the co-reactant is formic acid (HCOOH) or tert-butylamine (TBA). Note, similar co-reactants, such as other organic acids or other organic amines, will also work.

According to another aspect of the invention, provided is a method for atomic layer deposition (ALD) of metal, the method comprising at least one cycle of: a) exposing a surface of a substrate, the surface of the substrate comprising a metal portion comprising copper (Cu) or platinum (Pt) or cobalt (Co) or ruthenium (Ru) or another metal and an insulator portion comprising SiO₂, SiN, or SiCOH, to a metal-organic precursor comprising cobalt (Co) or ruthenium (Ru); b) depositing a metal-organic precursor on a surface of the metal portion of the substrate to selectively provide a metal precursor layer on the surface of the metal portion of the substrate; c) exposing the metal precursor layer to a co-reactant; and d) depositing the co-reactant on the metal precursor layer, wherein the co-reactant is formic acid (HCOOH) or tert-butylamine (TBA), and wherein deposition takes place between about 140° C. and about 230° C. Note, similar co-reactants, such as other organic acids other organic amines, will also work.

### BRIEF DESCRIPTION OF THE DRAWINGS

FIG. 1: XPS of UHV annealed Pt and SiO₂ substrates that underwent 100 cycles followed by an additional 100 ALD cycles of Co(DAD)₂+HCOOH at 180° C. For the Pt substrate, the loss of Pt signal in XPS is consistent with a deposited cobalt film >10 nm thick, while on SiO₂, no cobalt signal is observed indicating no deposition has occurred consistent with infinite selectivity.

FIG. 2: AFM imaging before and after ALD cycles on SiO₂ and Pt. On SiO₂, no change was observed, while the Co film on Pt had a sub 2 nm RMS surface roughness.

FIG. 3: Saturation Study of Co(DAD)₂ and HCOOH at 180° C. The self-limiting exposures were consistent with ALD. The increase in C and O after HCOOH dosing was consistent with deposition of a formate on the surface. The decrease in C and O, and increase in Co, after Co(DAD)₂ dosing indicated a ligand exchange mechanism for the reaction.

FIG. 4: Co 2p raw XPS Peaks. After formic acid dosing, a higher binding energy (BE) component is exhibited, consistent with a formate deposited on the Co surface. The formate is removed after Co(DAD)₂ dosing.

FIGS. 5A-5C: Co ALD with HCOOH vs TBA on Cu vs SiO₂. (FIG. 5A) No attenuation of the substrate Cu signal with HCOOH was consistent with etching of Cu/Cuₓ, (FIG. 5B) When ALD was performed with TBA, the Cu fully buried consistent with no etching. (FIG. 5C) 4% CoOₓ was observed after 50 cycles of Co(DAD)₂+TBA. No additional CoOₓ was observed after 250 additional ALD cycles consistent with hyper-selectivity.

FIG. 6: No selectivity from high temperature deposition with HCOOH.

FIG. 7: Strong selectivity from lowering the temperature to 215° C. and using HCOOH. Significant deposition is only occurring on Cu and not on SiO₂.

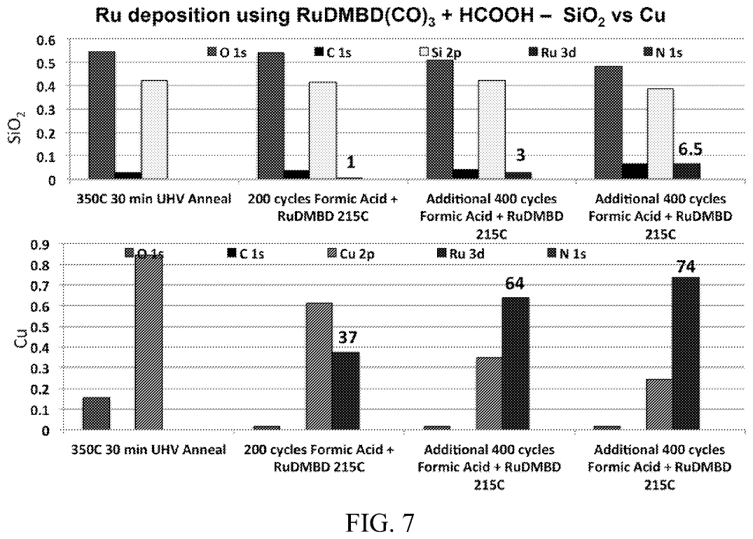

FIG. 8: Strong selectivity from lowering the temperature to 215° C. and using HCOOH. AFM on the left side shows the deposition on Cu (zoomed out and zoomed in); larger grains formed consistent with potential etching. Need to repeat with TBA. On the right is SiO₂, which just shows small nuclei.

FIG. 9: Selective Deposition with TBA. XPS on SiO₂ and passivated SiO₂ shows very little deposition after 600 total cycles compared to deposition on the Pt sample. There is almost 20:1 selectivity seen on Pt vs SiO₂.

FIG. 10: AFM showing resulting smooth film on Pt. Left: AFM showing the resulting smooth Ru film on Pt. Right: AFM shows the resulting Ru film on SiO₂, which appears to have more particles consistent with selectivity seen in XPS.

FIG. 11: Raw XPS Ru 3d Peaks on SiO₂ and Pt. The raw XPS peak gives further insight into the oxidation state of the Ru that was deposited. On Pt, the oxidation state is consistent with metallic Ru (BE of 279.8 eV), which the oxidation state of the Ru on SiO₂ is more consistent that of an oxide (BE of 280.3 eV). This allows one to gain insight into the mechanism of selectivity by forming an oxide on the surface, which prevents deposition.

FIG. 12. 200 Cycles of Co(DAD)₂+TBA at 180° C. on a Patterned Cu/SiO₂ structure. The Cu stripes are gray and the SiO₂ areas are black. (left) After 200 cycles on the unpassivated sample, unwanted Co nuclei are observed close to the Co/Cu stripes. (right) On a passivated sample, the density of unwanted nuclei is 4× lower and more uniform across SiO₂.

FIGS. 13a and 13b. 200 Cycles of Co(DAD)₂+TBA at 180° C. on a Patterned Cu/SiO₂ sample. The Cu stripes are grey and the SiO₂ areas are black. (FIG. 13a) Increasing pump-out time has weak effect on nucleation density. (FIG. 13b) The dose of Co(DAD)₂ in each cycle was reduced by 4×. Note the near perfect selectivity, but overall growth rate was reduced 2×.

FIG. 14. 200 Cycles of Co(DAD)₂+TBA at 180° C. on a Patterned Cu/SiO₂ sample with 260 C Periodic Anneal. The Cu stripes are grey and the SiCOH areas are black. (left) Note the near perfect selectivity. No passivation was employed, only a 5 second pumpout was employed, and saturation Co(DAD)₂ doses were employed to get maximum growth rate and conformal deposition.

### DETAILED DESCRIPTION

The foregoing and other aspects of the present invention will now be described in more detail with respect to other embodiments described herein. It should be appreciated that the invention can be embodied in different forms and should not be construed as limited to the embodiments set forth herein. Rather, these embodiments are provided so that this disclosure will be thorough and complete, and will fully convey the scope of the invention to those skilled in the art.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. Additionally, as used herein, the term “and/or” includes any and all combinations of one or more of the associated listed items and may be abbreviated as “/”.

Unless otherwise defined, all technical and scientific terms used herein have the same meaning as commonly understood by one of ordinary skill in the art to which this invention belongs.

Embodiments of the present invention provide ALD techniques, which enable the selective deposition of metals on a first surface or portion of a substrate, such as a metal surface, over a second surface of the substrate, such as an insulator surface, such as, but not limited to, an SiO₂ surface on a substrate. In some embodiments, deposition of a metal may be performed with, for example, Co and Ru, on, for example, a metal, such as Pt, Cu, Co, and/or Ru with selectivity over an insulator, for example, SiO₂ or SiCOH (a porous low-k dielectric), but the mechanism leading to selectivity can extend methods of the present invention to other metal precursors via co-reactants of formic acid or tert-butylamine (TBA) or related coreactants such as organic carboxylic acids and organic amines. In some embodiments, the substrate may be an unpatterned substrate. In other embodiments, the substrate may be a patterned substrate.

Embodiments of the present invention provide very selective Co and Ru metal deposition from either, for example, Co(DAD)₂ or Ru(DMBD)(CO)₃ metal precursors and two different co-reactants (HCOOH and TBA). In some embodiments, for example, Co deposition on, for example, Pt or Cu with HCOOH as a co-reactant, no deposition was seen on SiO₂ consistent with infinite selectivity on planar samples, however HCOOH was observed to etch Cu. By switching to TBA, no Cu etching was observed, and similar metallic Co films were deposited with only 4% CoOₓ on SiO₂ independent of the number of Co ALD cycles. The self-limiting deposition on SiO₂ is a novel mechanism of selectivity through the formation of an oxidic particulate, which results in hyper-selectivity.

The number of ALD cycles performed in the methods according to the present invention is not particularly limited, and may be as few as one cycle, and as many as about 2, 5, 10, 20, 30, 40, 50, 100, 150, 200, 300, 400, 500, 600, 700, 800, 900, to about 1,000 cycles, or more, or any number of cycles therebetween.

In embodiments of the present invention, deposition of metals by ALD results through a ligand exchange taking place between a metal precursor layer on, for example, the metal surface or portion of the substrate, and the co-reactant. For example, following exposure the metal surface or portion of the substrate to a metal precursor, such as Co(DAD)₂, to deposit/form the metal precursor layer on the substrate, exposure of the metal precursor layer to a co-reactant, thus depositing the co-reactant, such as, for example, HCOOH, on the metal precursor layer, results in, for example, formate on the metal precursor layer, i.e., the co-reactant participates in ligand exchange with the metal precursor layer.

Although HCOOH and TBA were described as giving selective Co ALD with Co(DAD)₂ by Winter et al., according to methods of the present invention, ALD selectivity approaches and becomes infinite due to specific control of pumping, purging, and wall temperature to remove CVD components in order to achieve ligand exchange, or molecular chemisorption, in contrast to the ALD described by Winter et al., who concluded that the HCOOH dissociatively chemisorbed to produce atomic H which removed the ligands from Co(DAD)₂. Important aspects of the specific control include (a) using a chamber base pressure of, for example, about 1×10⁻⁶ Torr to reduce background water, other reactive gasses, and co-reactants all of which can induce non-selective CVD, such as may be provided by using, for example, a turbomolecular pump (b) reducing surface contaminants, such as may be provided by using, for example, a turbomolecular pump (c) using long purge cycles (for example, about 15-30 seconds) to reduce leftover co-reactants which previous ½ cycle which can induce CVD, (d) using UHV high temperature pre-anneals at temperatures of about 250° C. to about 350° C. for about, for example, 30 minutes to reduce unwanted metal deposition on insulator surfaces, (e) controlling chamber wall temperature between about 80° C. to about 100° C. to reduce precursor remaining in chamber after each pulse, and (f) using optimized pulse times for each precursor. Pulsing and pumping times were optimized to be about 1 second for the precursors (pulsing times) separated by about 15 seconds of pumping (pumping times).

In some embodiments, longer purge times, for example, increasing purge times after exposing the substrate/sample to the metal-organic precursor from about 5 seconds to about 10, about 15 seconds, about 20 seconds, about 30 seconds, about 40 seconds, about 50 seconds, or even about 60 seconds, can be used to increase selectivity, especially for nanoscale patterned samples. In other embodiments, reducing the dose of the metal-organic precursor by, for example, reducing the number of pulses per cycle can be used to increase selectivity, especially for nanoscale patterned samples. In some embodiments, in order to increase selectivity, especially for nanoscale patterned samples, the dose of metal-organic precursor may be a sub-saturation dose. For example, the dose may be less than about 0.7×saturation, about 0.6×saturation, about 0.5×saturation, about 0.4×saturation, about 0.3×saturation, or about 0.2×saturation dose. Furthermore, in some embodiments, a periodic anneal between two cycles of ALD may be performed, for example, a periodic anneal after, for example but not limited to, about 10, 20, 50, 100, 150, or 200 ALD cycles, at a temperature that is below the reflow temperature of the metal deposited, for example, about 260° C. in the case of Co, followed by one, or more, for example, about 10, 20, 50, 100, 150 or 200 additional ALD cycles, can lead to increased selectivity especially for nanoscale patterned samples. In the case of Ru, the periodic anneal may take place at a temperature of, for example, closer to about 250° C. to 350° C. in the presence of O₂ or about 350° C. to about 400° C. in the absence of O₂.

In addition, temperature at which deposition takes place can be critical for selectivity. In some embodiments, selective ALD of Co may take place between about 160° C. and about 280° C. In some embodiments, the temperature at which selective ALD of Co takes place at about 180° C. In other embodiments, selective ALD of Ru may take place between about 160° C. and about 230° C. In some embodiments, selective ALD of Ru takes place at about 215° C.±15° C.

Furthermore, embodiments of the present invention provide a mechanism for hyper-selective ALD that can be extended to nearly any metal with a DAD ligand precursor.

ALD cobalt metal was deposited using a metal-organic cobalt precursor, Bis(1,4-di-tert-butyl-1,3-diazadienyl) cobalt (Co(DAD)₂), and either a co-reactant of formic acid (HCOOH) or tert-butylamine (TBA) at 180° C. on Cu, Pt, and SiO₂ substrates. The deposited Co films were studied using in-situ x-ray photoelectron spectroscopy (XPS) and atomic force microscopy (AFM). Cross-sectional scanning electron microscopy (SEM) and 4-point probe measurements were performed to check film thickness and resistivity, respectively.

ALD ruthenium metal was deposited using a zero-oxidation state liquid precursor, η⁴-2,3-dimethylbutadiene ruthenium tricarbonyl [Ru(DMBD)(CO)₃], and again either formic acid or TBA. Selectivity was seen again as Ru metal deposited on metal substrates (Pt and Cu) vs SiO₂. The ALD was run at 215° C. The deposition on both of these metals via a selective ALD process allows for via metal deposition with larger grains to lower via metal resistance.

Selective Co from HCOOH: it was found that there is nearly infinite selective deposition of Co on a conductor and not an SiO₂ for 180° C. ALD with Co(DAD)₂ and HCOOH. The ALD was run using a turbomolecular pumped system with a base pressure of 1×10⁻⁶ Torr with a wall temperature of 80° C. The Co(DAD)₂ precursor was heated to a bottle temperature of 150° C. to achieve sufficient vapor pressure, while HCOOH was dosed at room temperature. The ALD pulsing and pumping times were optimized to be 1 second for the precursors separated by 15 seconds of pumping.

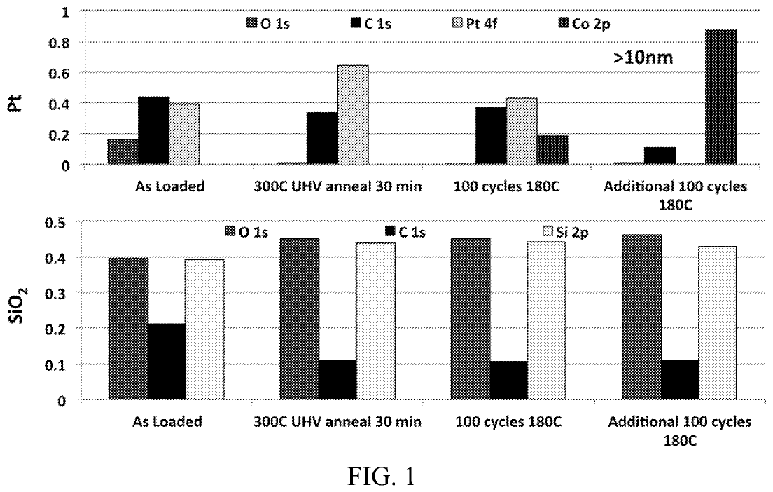

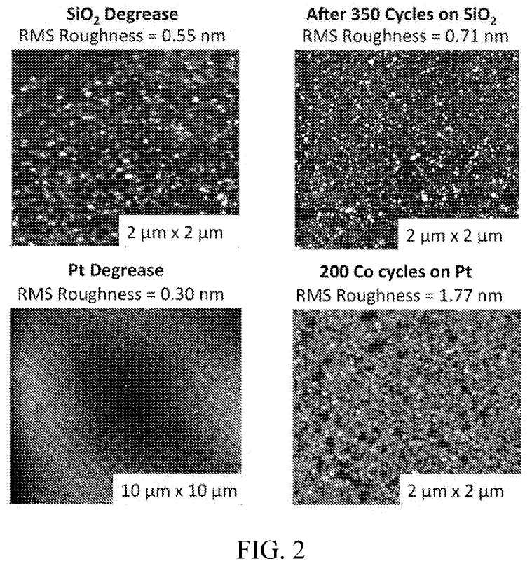

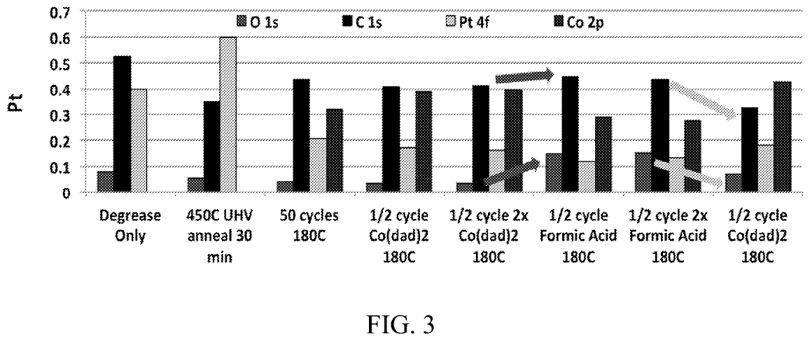

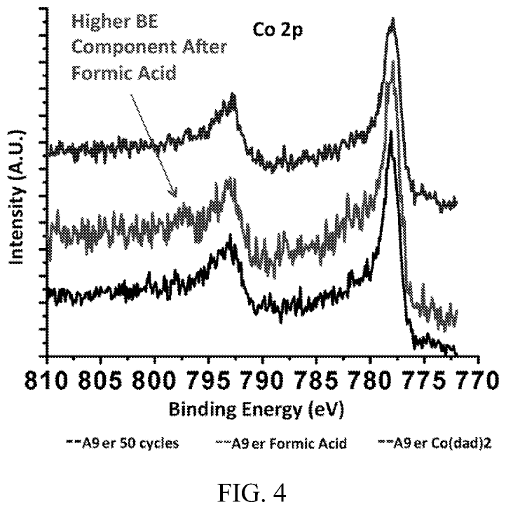

FIG. 1 shows the XPS of performing 100 ALD cycles followed by an additional 100 cycles on UHV annealed Pt vs SiO₂. On Pt, a thick (>10 nm) Co⁺⁰ film deposits while virtually no deposition results on SiO₂. AFM images show no change on SiO₂ before and after Co ALD cycles consistent with no nuclei formation, while the Co on Pt surface roughness remains below 1.8 nm (FIG. 2). To verify self-limiting precursor exposures consistent with ALD, a saturation study was performed and monitored with XPS. FIG. 3 highlights the effect of individual additional half cycle amounts that result in self-limiting Co(DAD)₂ and HCOOH exposures consistent with ALD. Additionally, this study revealed a novel mechanism about the reaction. In contrast to the cobalt layer ALD of Winter et al., in which it was concluded that HCOOH dissociatively chemisorbed to produce atomic H which removed the ligands from Co(DAD)₂, in the ALD of the present invention, XPS shows that HCOOH does not remove the ligands, but instead induce a ligand-exchange process. FIG. 4 shows a Co 2p peak that indicates the HCOOH leaving a higher binding energy component consistent with the presence of formate on the surface that is then removed upon exposure to Co(DAD)₂.

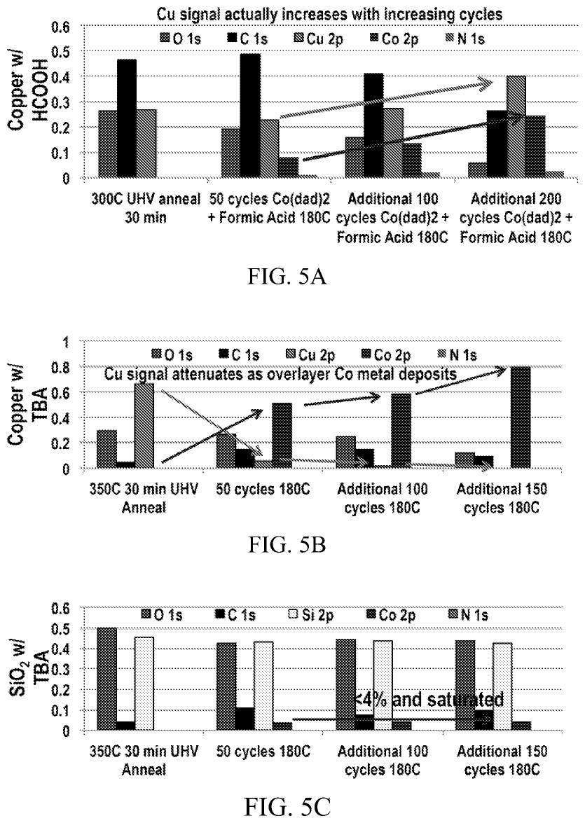

Selective Co from TBA: Deposition with HCOOH was attempted on Cu substrates (FIG. 5A); however, the substrate Cu signal never decreased to zero consistent with etching by HCOOH so an alkyl amine co-reactant (TBA) was also studied. For Co(DAD)₂+TBA ALD at 180° C., reduced Co metal films were deposited on Cu and Pt substrates with hyper-selectivity against SiO₂. Films as thick as 30 nm were grown on the conductors (FIG. 5B) without etching the substrates. On SiO₂, only 4% CoOₓ was deposited after an initial 50 ALD cycles. After an additional 250 ALD cycles, there was still only 4% CoOₓ consistent with saturation and hyper-selectivity (i.e. infinite selectivity) (FIG. 5C). AFM imaging from ALD with TBA confirmed low surface roughness ALD on Pt and Cu, while only small (<5 nm) CoOₓ particles were present on SiO₂.

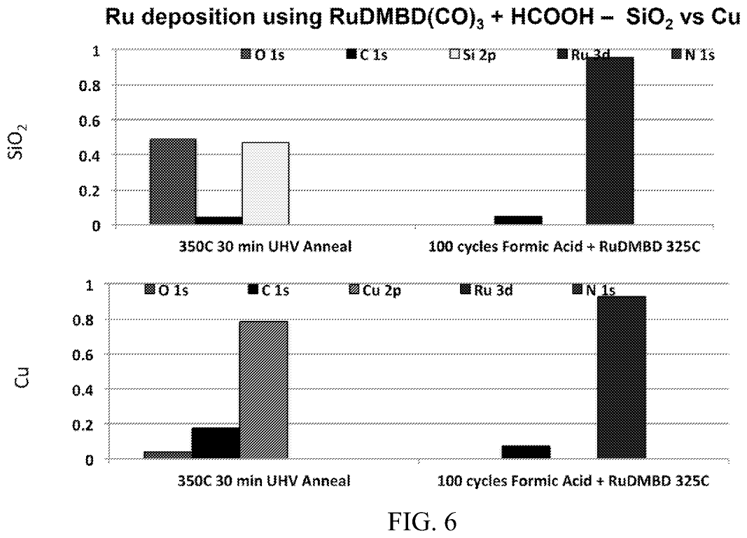

For Ru ALD, FIG. 6 shows the reaction at high temperature (325° C.). No selectivity on metals vs insulators is observed. However, when the temperature is dropped to 215° C., strong selectivity of Ru deposition on metals occurs with a very small amount of deposition on SiO₂. The ALD was run using a turbomolecular pumped system with a base pressure of 1×10⁻⁶ Torr with a wall temperature of 80° C. The Ru(DMBD)(CO)₃ precursor was gently heated to a bottle temperature of 30° C. to achieve sufficient vapor pressure, while HCOOH and TBA were again dosed from sources kept at room temperature. The ALD pulsing times were set to 1 second for the precursors separated by 15 seconds of pumping.

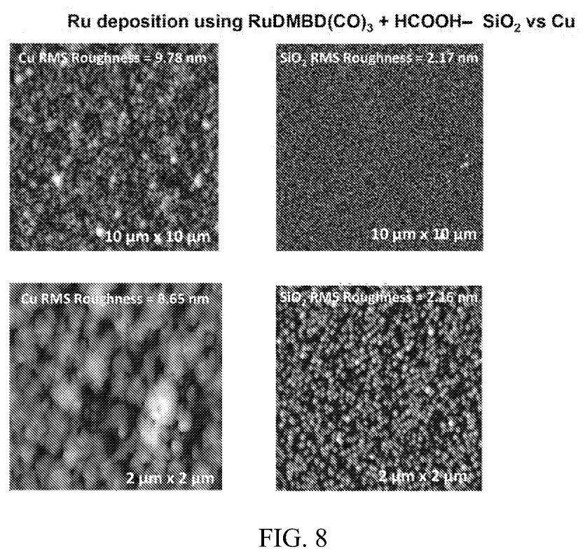

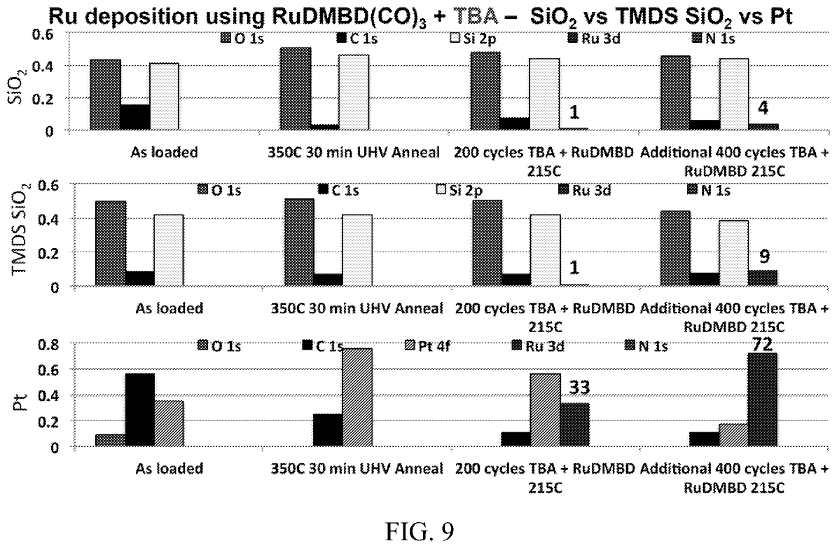

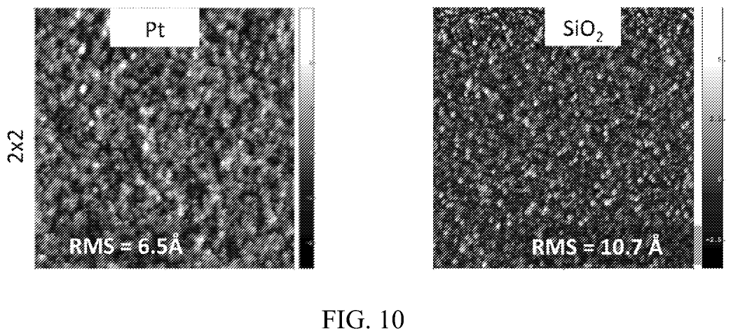

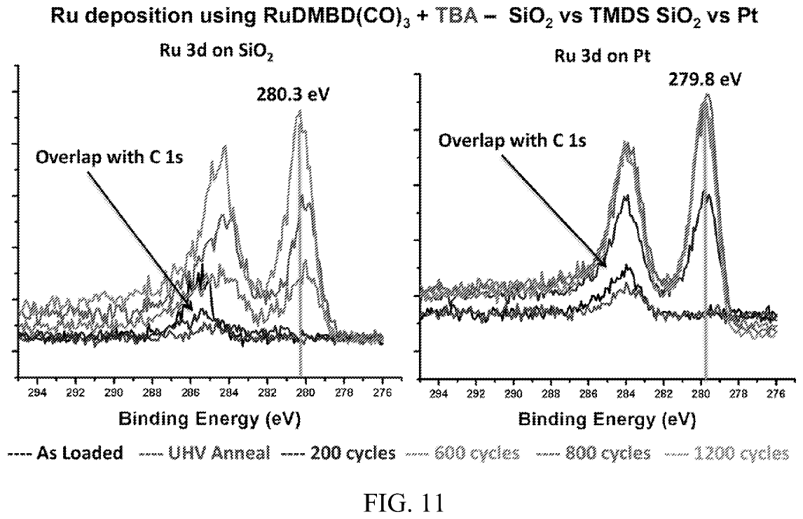

When looking in AFM to see the surface topography, the Ru deposition on Cu shows some larger grains consistent with the deposition, while there are only small nuclei on the SiO₂ consistent with good selectivity (FIG. 8) Since the films are a little more rough than ideal, the precursor was switched from formic acid to TBA (similar to the Co). When using TBA with the Ru(DMBD)(CO)₃, the selectivity was still very strong in XPS. FIG. 9. shows the amount of Ru that was deposited on each of the various substrates. FIG. 10. shows the AFM images by switching to a smoother platinum sample in comparison to the deposition on SiO₂. The AFM shows very low surface roughness consistent with a very smooth film of Ru being deposited. This smooth film is expected to be a very good choice for bottom up fill in vias. FIG. 11 shows the XPS chemical shift data of the Ru 3d peak in XPS for both the Pt and the SiO₂ substrates. For the SiO₂, the peak location is at 280.3 eV, while for the Pt, the peak is at 279.8 eV. This is very consistent with RuOₓ forming on the SiO₂ surface, while more reduced (metallic) Ru is forming on the Pt surface, indicating that by forming oxidized metallic components on the surface, deposition of reduced, metallic species is reduced but since the RuOₓ is not fully oxidized, the adsorption of the precursor is not fully blocked.

In other embodiments of the present invention, an ALD process is provided that can be used in MOL and BEOL, in which selectivity is maintained on the nanoscale level between the metal growth surface and the insulators, i.e., on patterned surfaces/substrates. Exemplary embodiments will now be described as follows.

According to embodiments of the present invention, atomic layer deposition of cobalt using Co(DAD)₂ and tertiary-butyl amine (TBA) has nearly infinite selectivity (>1000 cycles) on metal vs. insulator (SiO₂ or low-k SiCOH) planar samples. However, on patterned samples, selectivity under identical ALD conditions may be limited, due to the diffusion of molecularly-adsorbed metal precursor from reactive to non-reactive surfaces. Three strategies have been found to improve Co ALD selectivity: increasing the purge time, decreasing the precursor dose, and periodic annealing. While decreasing the precursor dose may be considered a conventional approach, the other two strategies are non-conventional. Increasing the purge time is especially effective for the Co(DAD)₂ precursor because it is able to reversibly molecularly adsorb and desorb from the sample; conversely, most precursors undergo rapid dissociative chemistry. The periodic annealing technique has not been previously reported for any system. The periodic annealing technique allows reabsorption of the Co nuclei from the insulator surface to the growth surface and is consistent with a low temperature reflow process.

Co ALD was performed using Co(DAD)₂+TBA at 180° C. on 85 nm wide Cu stripes on SiO₂. The planar structure of these stripes is used to demonstrate the effectiveness of passivation, as top-down SEM imagery and XPS quantification can be used to monitor growth and presence of unwanted Co nuclei on insulator. To control precursor dose, multiple precursor pulses were employed in each cycle to limit the maximum pressure. XPS is performed without breaking vacuum to prevent oxidation of Co.

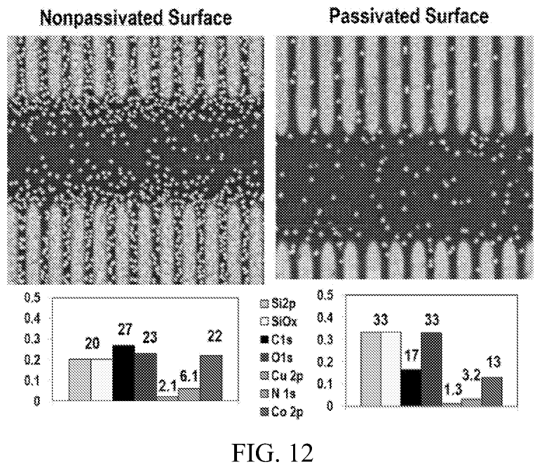

Breakdown of Selectivity on the Nanoscale: The Co(DAD)₂+TBA ALD process was employed on patterned substrates with 85 nm wide Cu lines separated by SiO₂. XPS quantification shows Cu attenuation and persistence of Si, consistent with selective deposition, but SEM imaging shows Co nuclei on the non-reactive SiO₂ surface (see FIG. 12). The nuclei are at high density near the Cu, tapering off with distance from the stripes. In addition, nearly all the nuclei are of similar diameter. This is consistent with unwanted nuclei being formed by diffusion of the Co(DAD)₂ precursor from the Co growth surface on the Cu to SiO₂ where it is converted to Co with a subsequent TBA pulse. On unpatterned SiO₂ surfaces, the observed hyper-selectivity is consistent with a lack of molecular adsorption, but it is hypothesized that hydroxyl groups on SiO₂ combined with the proximity of the Co/Cu surfaces may result in unwanted adsorption of Co precursor, and thus, unwanted nucleation.

To confirm this, the Cu/SiO₂ patterned sample was passivated with vapor-phase dimethylamino-dimethyl-silazane (DMADMS) and tetramethyl-disilazane (TMDS) for 10 minutes at 70° C. and 200 cycles of Co ALD performed. As shown in FIG. 12, the number of unwanted nuclei is reduced by at least 4x and the uniformity of the nuclei on the SiO₂ increased. This is consistent with the passivation of defect sites on the SiO₂, leaving Co(DAD)₂ with a longer surface diffusion path and more likely to readsorb on the metal stripes.

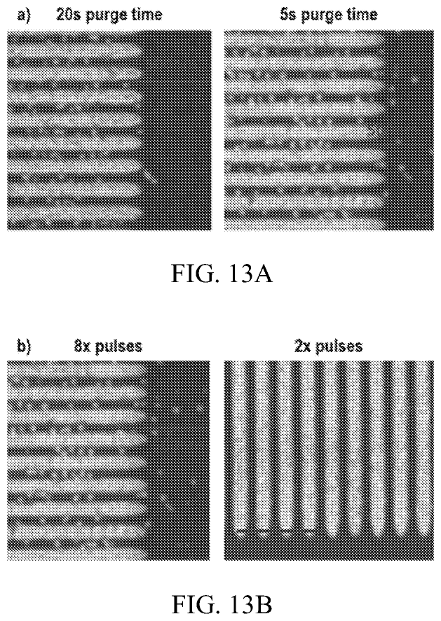

Two Methods of Diffusion Control: The Co(DAD)₂+TBA ALD is unusual because XPS data is consistent with molecular instead of dissociative chemisorption of Co(DAD)₂ at 180C. This implies that the Co(DAD)2 adsorption is reversible; therefore it was hypothesized that selectivity could also be improved by increasing the purge time, so Co(DAD)₂ which diffused onto the SiO₂ can desorb before the pulse of TBA removed the (DAD) ligands from Co(DAD)₂, inducing irreversible adsorption. As shown in FIG. 13a, increasing the purge time from 5 second to 20 seconds decreased the density of unwanted nuclei consistent with the Co(DAD)₂ diffusion and reversible adsorption, but the effect is less drastic than the effect of passivation.

The Co(DAD)₂ likely adsorbs strongly to the Co metallic growth surface, but during each ALD cycle, excess Co(DAD)₂ is employed to ensure saturation so the growth surface is not metallic Co at the end of the Co(DAD)₂ dosing. It was hypothesized that once the growth surface was saturated with Co(DAD)₂, further Co(DAD)₂ dosing would result in diffusion onto the SiO₂. To test this, a lower Co(DAD)₂ dose was employed by reducing the number of pulses per cycle. As shown in FIG. 13b, this was very effective in reducing the number of unwanted nuclei on the SiO₂, but also reduced the growth rate. The results confirm that the loss of selectivity on the nanoscale is due to surface precursor diffusion.

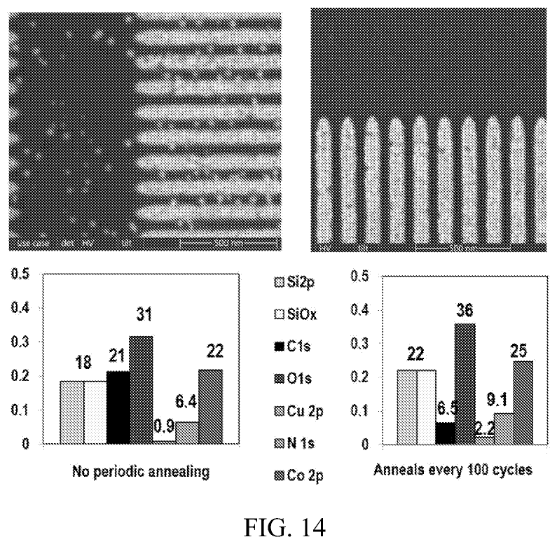

Removal of Unwanted Nuclei by Nano-Reflow: A third method to improve selectivity was tested; after each 100 Co ALD cycles, an anneal to 260° C. was performed; this is about 100° C. below the normal Co reflow temperature. However, according to the simple Ostwald ripening model, atoms from small nuclei can more readily diffuse than atoms from large nuclei; therefore, by annealing the sample when the nuclei are small, it may be possible to induce Co diffusion from the nuclei to the Co/Cu stripes. As shown in FIG. 14, periodic annealing resulted in near perfect selectivity on a Cu/SiO₂ pattern without passivation. This technique has the added advantage of allowing a lower temperature for reflow, potentially allowing a scaling of the diffusion barrier between the Co and the SiCOH which is normally employed. Note this method of increasing selectivity for Co and reducing the need for high temperature reflow may also be useful for other selective Co ALD and CVD processes. Note this method as well as the two other methods (purge time increase and metal dose decrease) may also be effective for increasing selectivity on the nanoscale and for the Ru ALD process of Ru(DMBD)(CO)₃+HCOOH or TBA. It is noted that for the Ru reflow, the annealing might be done while dosing O₂ since RuOx may diffuse faster than Ru at a given temperatures

While specific embodiments of the present invention have been shown and described, it will be understood that other modifications, substitutions and alternatives are apparent to one of ordinary skill in the art. Such modifications, substitutions and alternatives can be made without departing from the spirit and scope of the invention, which should be determined from the appended claims.

Various features of the invention are set forth in the appended claims.

1. A method for atomic layer deposition (ALD) of a metal, the method comprising at least one cycle of:
a) exposing a substrate, the substrate comprising a surface comprising a metal portion and an insulator portion, to a metal-organic precursor;
b) depositing the metal-organic precursor on a surface of the metal portion of the substrate to selectively provide a metal precursor layer on the surface of the metal portion of the substrate;
c) exposing the metal precursor layer to a co-reactant; and
d) depositing the co-reactant on the metal precursor layer, wherein the co-reactant takes part in a ligand exchange with the metal precursor layer.

2. The method of claim 1, wherein the cycle of a), b), c) and d) is performed more than one time.

3. The method of claim 2, wherein a periodic anneal is performed between two cycles of a), b), c) and d).

4. The method of claim 3, wherein the periodic anneal is performed at about 260° C. if the metal-organic precursor comprises Co, or about 250° C. to about 350° C. in the presence of O₂, or about 350° C. to about 400° C. in the absence of O₂ if the metal-organic precursor comprises Ru.

5. The method of claim 1, wherein exposing the substrate to a metal-organic precursor comprises a pulse time of about 1 second.

6. The method of claim 1, wherein the substrate is exposed to a sub-saturation dose (<0.7×saturation) of the metal-organic precursor.

7. The method of claim 1, further comprising purging excess metal-organic precursor for a period of about 20 seconds to about 60 seconds after step a).

8. The method of claim 1, wherein the co-reactant is formic acid (HCOOH) or tert-butylamine (TBA), or similar organic carboxylic acid or organic amine.

9. The method of claim 1, wherein the metal-organic precursor is bis(1,4-di-tert-butyl-1,3-diazenyl) cobalt [Co(DAD)₂].

10. The method of claim 1, wherein deposition takes place between about 160° C. and about 200° C.

11. The method of claim 10, wherein deposition takes place at about 180° C.,

12. The method of claim 1, wherein the substrate comprises a metal portion comprising copper (Cu), or platinum (Pt) or cobalt (Co) or ruthenium (Ru) and deposition on the metal portion of the substrate is selective over deposition on an insulating portion of the substrate comprising SiO₂, SiN, or SiCOH.

13. The method of claim 12, wherein the insulating portion of the substrate comprises SiO₂.

14. The method of claim 1, wherein the ligand exchange is induced through control of gas phase CVD.

15. A method for atomic layer deposition (ALD) of a metal, the method comprising at least one cycle of:
a) exposing a substrate, the substrate comprising a surface comprising a metal portion and an insulator portion, to a zero-oxidation state liquid metal-organic precursor;
b) depositing the zero-oxidation state liquid metal-organic precursor on an upper surface of the metal portion of the substrate to selectively provide a metal precursor layer on the upper surface of the metal portion of the substrate;
c) exposing the metal precursor layer to a co-reactant; and
d) depositing the co-reactant on the metal precursor layer,
wherein the co-reactant is formic acid (HCOOH) or tert-butylamine (TBA), or similar organic carboxylic acid or organic amine.

16-23. (canceled)

24. A method for atomic layer deposition (ALD) of metal, the method comprising at least one cycle of:
a) exposing a surface of a substrate, the surface of the substrate comprising a metal portion comprising copper (Cu), platinum (Pt), cobalt (Co) or ruthenium (Ru) and an insulator portion comprising SiO₂, SiN, or SiCOH, to a metal-organic precursor comprising cobalt (Co) or ruthenium (Ru);
b) depositing a metal-organic precursor on an upper surface of the metal portion of the substrate to selectively provide a metal precursor layer on the upper surface of the metal portion of the substrate;
c) exposing the metal precursor layer to a co-reactant; and
d) depositing the co-reactant on the metal precursor layer,
wherein the co-reactant is formic acid (HCOOH) or tert-butylamine (TBA), and wherein deposition takes place between about 160° C. and about 230° C.

25-26. (canceled)

27. The method of claim 24, wherein the metal-organic precursor is bis(1,4-di-tert-butyl-1,3-diazenyl) cobalt [Co(DAD)₂], the co-reactant is HCOOH, the metal portion of the substrate comprises Pt, Cu, Co or Ru, and wherein deposition takes place at about 180° C.

28. The method of claim 24, wherein the metal-organic precursor is bis(1,4-di-tert-butyl-1,3-diazenyl) cobalt [Co(DAD)₂], the co-reactant is TBA, the metal portion of the substrate comprises Cu, Pt, Co or Ru, and wherein deposition take place at about 180° C.

29-34. (canceled)
